(19) United States
(12) Patent Application Publication
(10) Pub. No.: US 2018/0287081 A1
(43) Pub. Date: Oct. 4, 2018

(54) VERTICAL CHANNEL ORGANIC THIN-FILM TRANSISTOR AND MANUFACTURING METHOD THEREOF

(71) Applicant: Wuhan China Star Optoelectronics Technology Co., Ltd., Wuhan City (CN)

(72) Inventor: Zhe Liu, Wuhan City (CN)

(21) Appl. No.: 15/539,700

(22) PCT Filed: Apr. 19, 2017
(86) PCT No.: PCT/CN2017/081029

§ 371 Date: Jun. 26, 2017

(30) Foreign Application Priority Data
Mar. 28, 2017 (CN) 201710194175.4

(51) Int. Cl. H01L 51/05; H01L 51/10; H01L 27/32

(52) U.S. Cl. CPC H01L 51/057; H01L 27/3274; H01L 51/105

(57) ABSTRACT

The present invention provides a vertical channel organic thin-film transistor and a manufacturing method thereof. The vertical channel organic thin-film transistor includes: an annular organic semiconductor layer, an annular drain electrode and an annular source electrode respectively set in contact with upper and lower sides of the annular organic semiconductor layer, and a gate electrode arranged inwardly of an inner circle of the annular organic semiconductor layer and insulated and isolated from the annular organic semiconductor layer. An effective conductive channel length of the thin-film transistor can be varied by changing a thickness of the organic semiconductor layer made with a solution method so that the definition of a short channel pattern no longer relies upon high precision exposure and etching equipment and thus, the difficulty and the cost of the manufacturing process can be reduced. Further, the annular electrode structure makes it possible to save a planar space of the thin-film transistor, increasing scenarios of application of the thin-film transistor, and improving flexibility of circuit design.

### BACKGROUND OF THE INVENTION

### 1. Field of the Invention

The present invention relates to the field of display technology, and more particular to a vertical channel organic thin-film transistor (TFT) and a manufacturing method thereof.

### 2. The Related Arts

With the development of the display technology, all sorts of flat panel display devices, including liquid crystal displays (LCDs) and organic light emitting displays (OLEDs), which show various advantages, such as high image quality, low power consumption, thin device body, and a wide range of applications, have been widely used in various consumer electronic products, such as mobile phones, televisions, personal digital assistants (PDAs), digital cameras, notebook computers, and desktop computers and are becoming a main stream of display devices.

A thin-film transistor (TFT) is an electronic switching element that is commonly used in flat panel display devices and is generally constructed with a gate electrode, an active layer, a gate insulation layer separating the gate electrode and the active layer from each other; and a source electrode and a drain electrode that are in contact with the active layer and are spaced from each other. Based on the location where the gate electrode is arranged, the thin-film transistors are classified as a bottom gate structure and a top gate structure; and based on the positional sequences of the source and drain electrodes and the active layer, the thin-film transistors are classified as a bottom contact electrode structure and a top contact electrode structure. Consequently, common structures of the thin-film transistors include four types: bottom gate and bottom contact electrode structure, bottom gate and top contact electrode structure, top gate and bottom contact electrode structure, and top gate and top contact electrode structure.

In these four structures, the source electrode and the drain electrode are located on the same film layer and an effective conductive channel length of each of the thin-film transistors is determined by a length of a channel located between the source electrode and the drain electrode measured in a horizontal direction. Thus, for a smaller length of the channel, the requirement for accuracy of vacuum equipment, particularly exposure and etching equipment, is severer, and particularly, when the channel design of thin-film transistors of an array contained in a display panel is one micrometer or less than one micrometer, control of precision of a manufacturing process would become a severe challenge.

Organic thin-film transistors are a kind of thin-film transistor that uses an organic semiconductor material to make the active layer. Compared to traditional silicon based thin-film transistors, the organic thin-film transistors possess advantages, such as being capable of handling in a low temperature with a solution-based process, having a reduced weight, capable of being integrated in a large area, and being compatible with flexible substrates, and are now being widely used in various display devices.

### SUMMARY OF THE INVENTION

Objectives of the present invention are to provide a vertical channel organic thin-film transistor, which reduces the difficulty and manufacturing cost of making a short channel pattern and saves a planar space of the thin-film transistor.

Objectives of the present invention are also to provide a manufacturing method of a vertical channel organic thin-film transistor, which reduces the difficulty and manufacturing cost of making a short channel pattern and saves a planar space of the thin-film transistor.

To achieve the above objectives, the present invention provides a vertical channel organic thin-film transistor, which comprises: a base plate, an annular source electrode arranged on the base plate, an annular organic semiconductor layer arranged on the source electrode and a portion of the base plate inwardly of an inner circle of the source electrode, an insulation layer set on and covering the base plate, the source electrode, and the organic semiconductor layer, an annular via extending through a portion of the insulation layer located atop the organic semiconductor layer, an annular drain electrode arranged in the annular via and in contact with the organic semiconductor layer, and a gate electrode arranged on a portion of the insulation layer inwardly of an inner circle of the organic semiconductor layer.

The source electrode, the organic semiconductor layer, the drain electrode, and the gate electrode have a common circle center.

The organic semiconductor layer is made with a solution method.

The vertical channel organic thin-film transistor is applicable to a flexible flat panel display device.

The organic semiconductor layer is formed of a material comprising a small-molecule organic semiconductor material or a polymer organic semiconductor material.

The present invention also provides a manufacturing method of a vertical channel organic thin-film transistor, which comprises the following steps:

Step 1: providing a base plate and forming an annular source electrode on the base plate;

Step 2: forming an annular organic semiconductor layer on the source electrode and a portion of the base plate inwardly of an inner circle of the source electrode;

Step 3: depositing an insulation layer on the base plate, the source electrode, and the organic semiconductor layer and subjecting the insulation layer to patterning to form an annular via that extends through a portion of the insulation layer located atop the organic semiconductor layer;

Step 4: forming an annular drain electrode in the annular via, such that the drain electrode is in contact with the organic semiconductor layer; and

Step 5: forming a gate electrode on a portion of the insulation layer inwardly of an inner circle of the organic semiconductor layer.

Step 2 applies a solution method to form the organic semiconductor layer and includes process that includes: coating or spin-coating an organic semiconductor material solution on the base plate and the source electrode, followed by baking and curing to form an organic semiconductor material film, and then subjecting the organic semiconductor material film to patterning to form the organic semiconductor layer.

In Step 2, subjecting the organic semiconductor material film to patterning is conducted by sequentially subjecting the organic semiconductor material film to exposure, development, and etching operations.

The organic semiconductor layer is formed of a material comprising a small-molecule organic semiconductor material or a polymer organic semiconductor material.

Step 1 includes: depositing a first metal film on the base plate 1 and then patterning the first metal film to form the annular source electrode;

Step 4 includes: depositing a second metal film on the insulation layer and then patterning the second metal film to form the annular drain electrode; and

Step 5 includes: depositing a third metal film on the insulation layer and then patterning the third metal film to form the gate electrode.

The present invention further provides a vertical channel organic thin-film transistor, which comprises: a base plate, an annular source electrode arranged on the base plate, an annular organic semiconductor layer arranged on the source electrode and a portion of the base plate inwardly of an inner circle of the source electrode, an insulation layer set on and covering the base plate, the source electrode, and the organic semiconductor layer, an annular via extending through a portion of the insulation layer located atop the organic semiconductor layer, an annular drain electrode arranged in the annular via and in contact with the organic semiconductor layer, and a gate electrode arranged on a portion of the insulation layer inwardly of an inner circle of the organic semiconductor layer;

wherein the source electrode, the organic semiconductor layer, the drain electrode, and the gate electrode have a common circle center; and

wherein the organic semiconductor layer is made with a solution method.

The efficacy of the present invention is that the present invention provides a vertical channel organic thin-film transistor, which comprises: an annular organic semiconductor layer, an annular drain electrode and an annular source electrode respectively set in contact with upper and lower sides of the annular organic semiconductor layer, and a gate electrode arranged inwardly of an inner circle of the annular organic semiconductor layer and insulated and isolated from the annular organic semiconductor layer, wherein an effective conductive channel length of the thin-film transistor can be varied by changing a thickness of the organic semiconductor layer made with a solution method so that the definition of a short channel pattern no longer relies upon high precision exposure and etching equipment and thus, the difficulty and the cost of the manufacturing process can be reduced. Further, the annular electrode structure makes it possible to save a planar space of the thin-film transistor, increasing scenarios of application of the thin-film transistor, and improving flexibility of circuit design. The present invention also provides a manufacturing method of a vertical channel organic thin-film transistor, which reduces manufacture difficulty and manufacturing cost of a short channel pattern and saves a planar space of the thin-film transistor.

### BRIEF DESCRIPTION OF THE DRAWINGS

For better understanding of the features and technical contents of the present invention, reference will be made to the following detailed description of the present invention and the attached drawings. However, the drawings are provided only for reference and illustration and are not intended to limit the present invention.

In the drawings:

FIG. 1 is a cross-sectional view illustrating Step 1 of a manufacturing method of a vertical channel organic thin-film transistor according to the present invention;

FIG. 2 is a top plan view illustrating Step 1 of the manufacturing method of a vertical channel organic thin-film transistor according to the present invention;

FIG. 3 is a cross-sectional view illustrating Step 2 of the manufacturing method of a vertical channel organic thin-film transistor according to the present invention;

FIG. 4 is a top plan view illustrating Step 2 of the manufacturing method of a vertical channel organic thin-film transistor according to the present invention;

FIG. 5 is a cross-sectional view illustrating Step 3 of the manufacturing method of a vertical channel organic thin-film transistor according to the present invention;

FIG. 6 is a top plan view illustrating Step 3 of the manufacturing method of a vertical channel organic thin-film transistor according to the present invention;

FIG. 7 is a cross-sectional view illustrating Step 4 of the manufacturing method of a vertical channel organic thin-film transistor according to the present invention;

FIG. 8 is a top plan view illustrating Step 4 of the manufacturing method of a vertical channel organic thin-film transistor according to the present invention;

FIG. 9 is a cross-sectional view illustrating Step 5 of the manufacturing method of a vertical channel organic thin-film transistor according to the present invention and is also a cross-sectional view illustrating a vertical channel organic thin-film transistor according to the present invention;

FIG. 10 is a top plan view illustrating Step 5 of the manufacturing method of a vertical channel organic thin-film transistor according to the present invention and is also a top plan view illustrating the vertical channel organic thin-film transistor according to the present invention; and

FIG. 11 is a flow chart illustrating the manufacturing method of a vertical channel organic thin-film transistor according to the present invention.

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

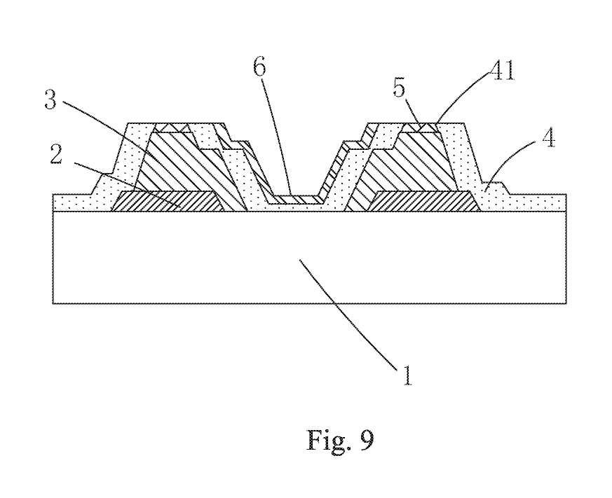

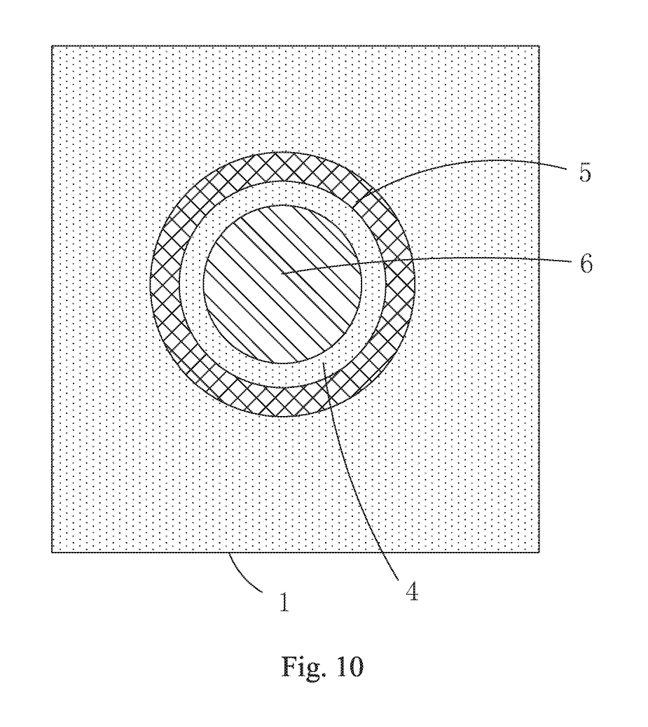

Referring to FIGS. 9 and 10, the present invention provides a vertical channel organic thin-film transistor, which comprises: a base plate 1, an annular source electrode 2 arranged on the base plate 1, an annular organic semiconductor layer 3 arranged on the source electrode 2 and a portion of the base plate 1 inwardly of an inner circle of the source electrode 2, an insulation layer 4 set on and covering the base plate 1, the source electrode 2, and the organic semiconductor layer 3, an annular via 41 extending through a portion of the insulation layer 4 located atop the organic semiconductor layer 3, an annular drain electrode 5 arranged in the annular via 41 and in contact with the organic semiconductor layer 3, and a gate electrode 6 arranged on a portion of the insulation layer 4 inwardly of an inner circle of the organic semiconductor layer 3.

Specifically, the source electrode 2, the organic semiconductor layer 3, the drain electrode 5, and the gate electrode 6 have a common circle center, wherein the source electrode 2 has an outside diameter that is greater than an outside diameter of the organic semiconductor layer 3 and the organic semiconductor layer 3 has an inside diameter that is smaller than an inside diameter of the source electrode 2; and the gate electrode 6 shows a circular form in a top plan view.

Specifically, the organic semiconductor layer 3 is made with a solution method, of which a specific process includes: coating or spin-coating an organic semiconductor material solution on the base plate 1 and the source electrode 2, followed by baking and curing to form an organic semiconductor material film, and then subjecting the organic semiconductor material film to patterning to form the organic semiconductor layer 3.

Further, the organic semiconductor layer 3 is formed of a material comprising a small-molecule organic semiconductor material or a polymer organic semiconductor material. Specifically, the small-molecule organic semiconductor material can be pentacene, triphenyl amine, fullerene, phthalocyanine, perylene derivatives, or gallocyanine; and the polymer organic semiconductor material can be a polymer material in the form of polyacetylenes, polycyclic aromatics, or copolymers.

It is noted that the vertical channel organic thin-film transistor is applicable to flexible flat panel display devices including flexible OLED display devices to fully exploit the characteristics of the organic thin-film transistor.

It is noted that in the present invention, the annular drain electrode 5 and the annular source electrode 2 are respectively located at upper and lower sides of the organic semiconductor layer 3 wherein an effective conductive channel length of the thin-film transistor can be varied by changing a thickness of the organic semiconductor layer 3 made with a solution method so that the definition of a short channel pattern no longer relies upon high precision exposure and etching equipment and thus, the difficulty and the cost of the manufacturing process can be reduced. Further, the annular electrode structure makes it possible to save a planar space of the thin-film transistor, increasing scenarios of application of the thin-film transistor, and improving flexibility of circuit design.

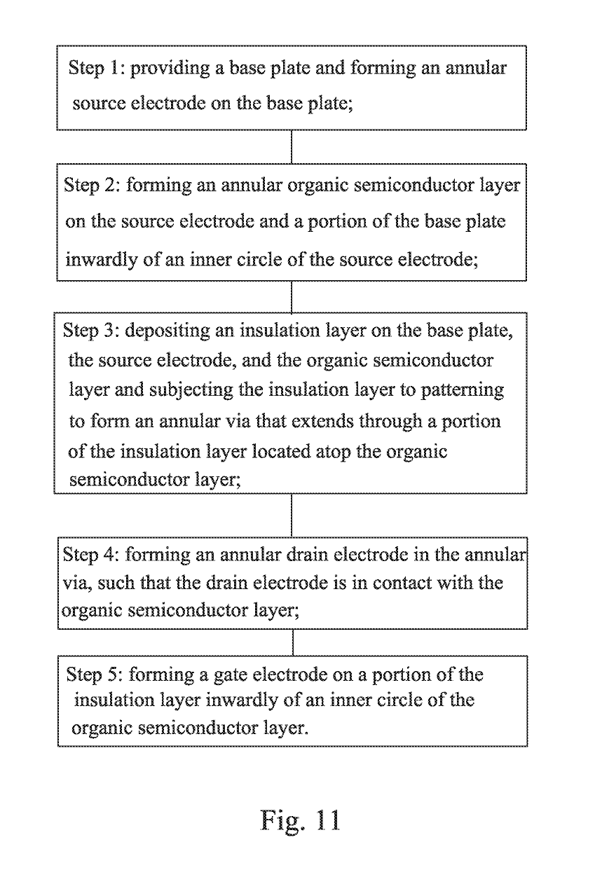

Referring to FIG. 11, the present invention further provides a manufacturing method for the above-described vertical channel organic thin-film transistor, which comprises the following steps:

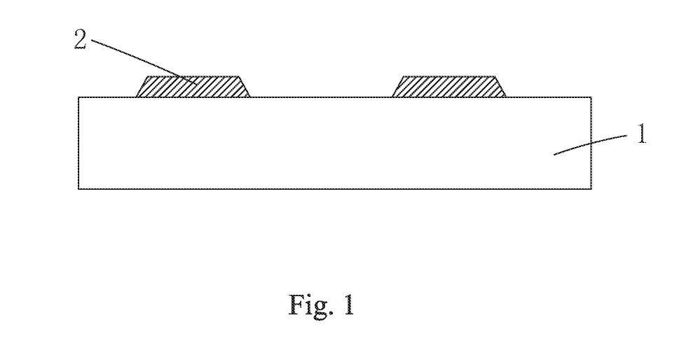

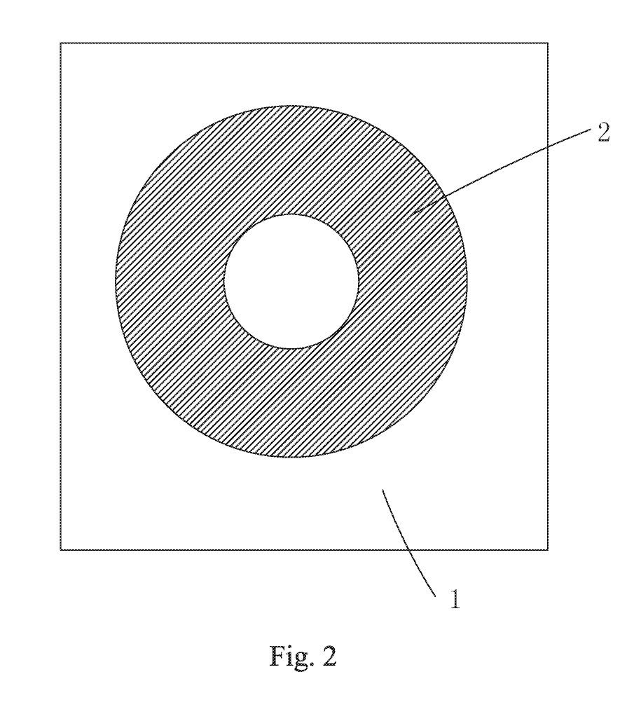

Step 1: referring to FIGS. 1 and 2, providing a base plate 1 and forming an annular source electrode 2 on the base plate 1.

Specifically, the base plate 1 comprises a glass plate, and the source electrode 2 is formed of a material comprising one of metals including aluminum, molybdenum, and copper or a combination of multiple ones thereof. Step 1 specifically includes: depositing a first metal film on the base plate 1 and then patterning the first metal film to form the annular source electrode 2.

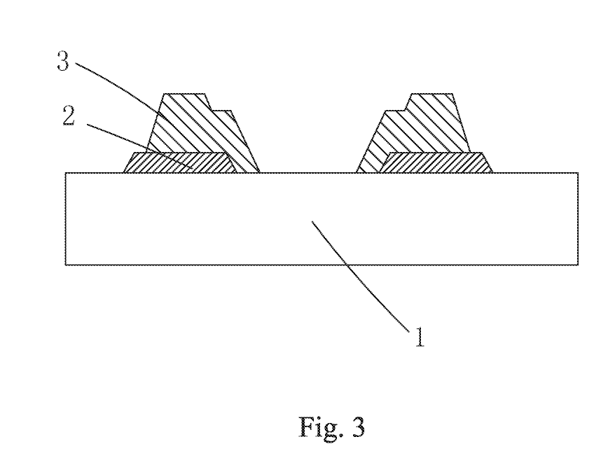

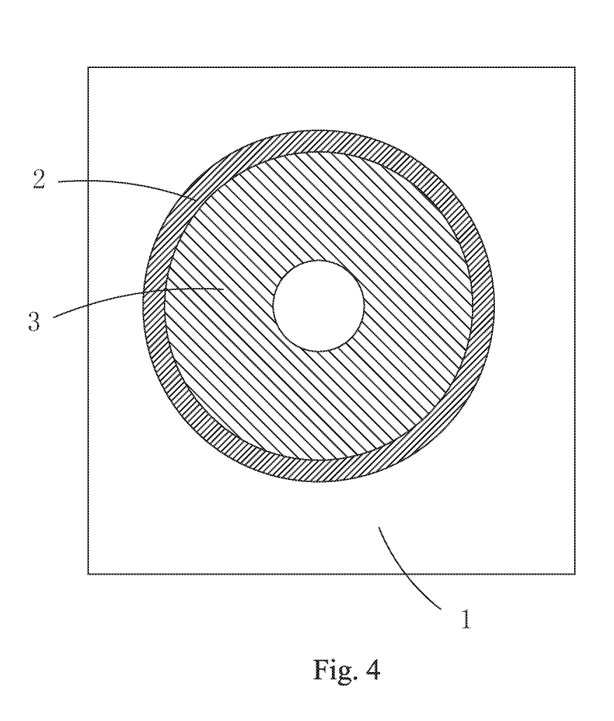

Step 2: referring to FIGS. 3 and 4, forming an annular organic semiconductor layer 3 on the source electrode 2 and a portion of the base plate 1 inwardly of an inner circle of the source electrode 2.

Specifically, Step 2 applies a solution method to form the organic semiconductor layer 3, and a specific process includes: coating or spin-coating an organic semiconductor material solution on the base plate 1 and the source electrode 2, followed by baking and curing to form an organic semiconductor material film, and then subjecting the organic semiconductor material film to patterning to form the organic semiconductor layer 3

Further, in Step 2, subjecting the organic semiconductor material film to patterning is conducted by sequentially subjecting the organic semiconductor material film to exposure, development, and etching operations.

Specifically, the organic semiconductor layer 3 is formed of a material comprising a small-molecule organic semiconductor material or a polymer organic semiconductor material. Specifically, the small-molecule organic semiconductor material can be pentacene, triphenyl amine, fullerene, phthalocyanine, perylene derivatives, or gallocyanine; and the polymer organic semiconductor material can be a polymer material in the form of polyacetylenes, polycyclic aromatics, or copolymers.

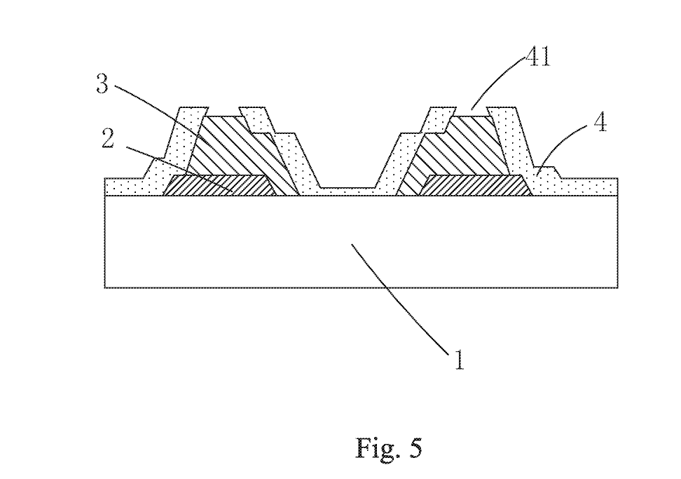

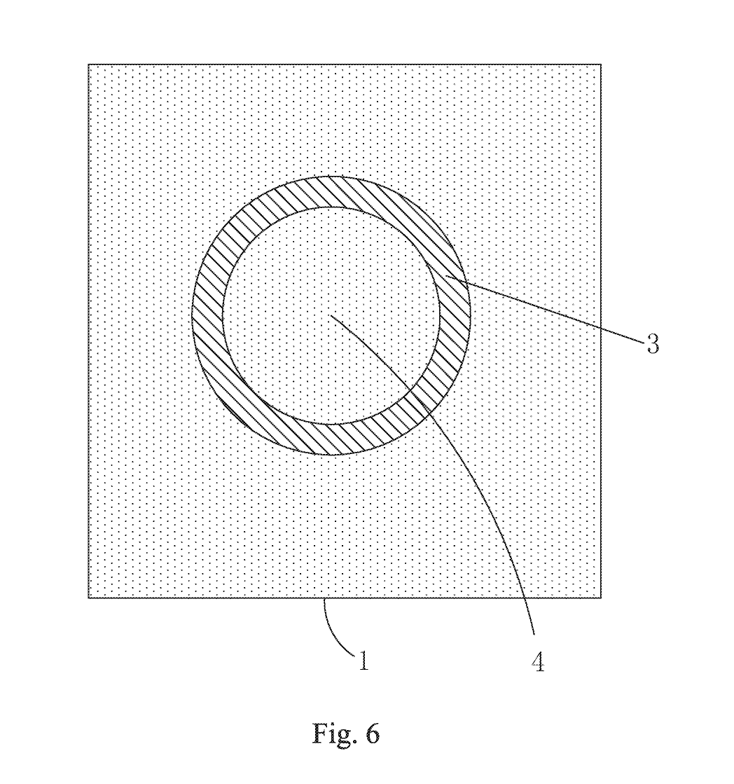

Step 3: referring to FIGS. 5 and 6, depositing an insulation layer 4 on the base plate 1, the source electrode 2, and the organic semiconductor layer 3 and subjecting the insulation layer 4 to patterning to form an annular via 41 that extends through a portion of the insulation layer 4 located atop the organic semiconductor layer 3.

Preferably, the insulation layer 4 is formed of a material comprising an organic dielectric material.

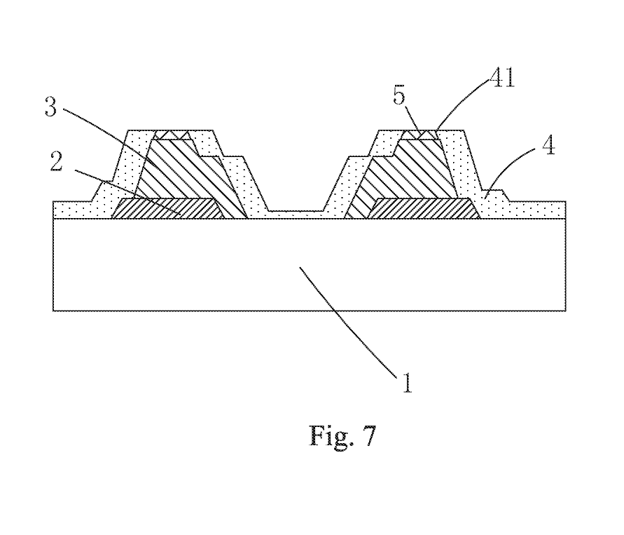

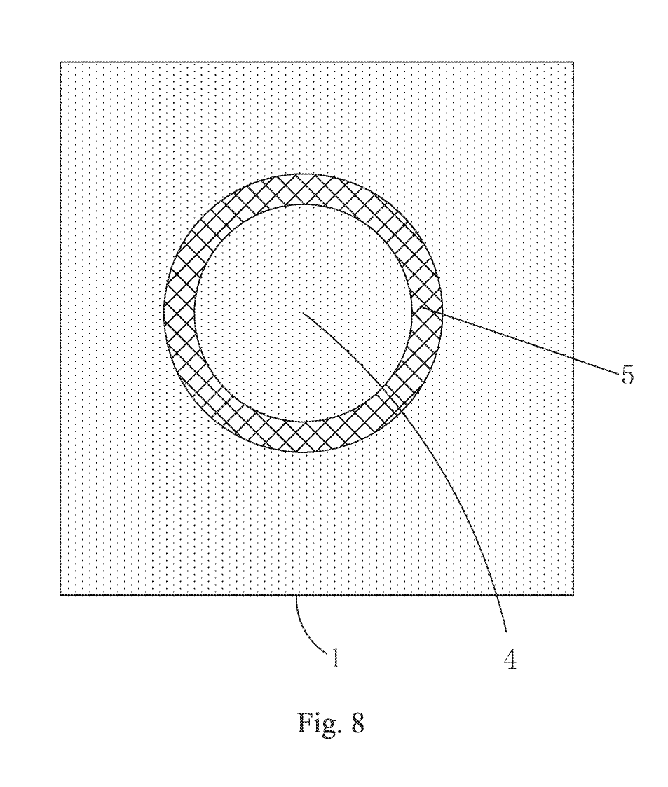

Step 4: referring to FIGS. 7 and 8, forming an annular drain electrode 5 in the annular via 41, such that the drain electrode 5 is in contact with the organic semiconductor layer 3.

Specifically, Step 4 specifically includes: depositing a second metal film on the insulation layer 4 and then patterning the second metal film to form the annular drain electrode 5. The drain electrode 5 is formed of a material comprising one of metals including aluminum, molybdenum, and copper or a combination of multiple ones thereof.

It is noted that the annular drain electrode 5 and the annular source electrode 2 are respectively located at upper and lower sides of the organic semiconductor layer 3 so that an effective conductive channel length of the thin-film transistor can be varied by changing a thickness of the organic semiconductor layer 3 made with a solution method so that the definition of a short channel pattern no longer relies upon high precision exposure and etching equipment and thus, the difficulty and the cost of the manufacturing process can be reduced. Further, the annular electrode structure makes it possible to save a planar space of the thin-film transistor, increasing scenarios of application of the thin-film transistor, and improving flexibility of circuit design.

Step 5: referring to FIGS. 9 and 10, forming a gate electrode 6 on a portion of the insulation layer 4 inwardly of an inner circle of the organic semiconductor layer 3.

Specifically, Step 5 specifically includes: depositing a third metal film on the insulation layer 4 and then patterning the third metal film to form the gate electrode 6. The gate electrode 6 is formed of a material comprising one of metals including aluminum, molybdenum, and copper or a combination of multiple ones thereof.

Further, the source electrode 2, the organic semiconductor layer 3, the drain electrode 5, and the gate electrode 6 have a common circle center, wherein the source electrode 2 has an outside diameter that is greater than an outside diameter of the organic semiconductor layer 3 and the organic semiconductor layer 3 has an inside diameter that is smaller than an inside diameter of the source electrode 2; and the gate electrode 6 shows a circular form in a top plan view.

It can be appreciated that based on the manufacturing method of a vertical channel organic thin-film transistor provided above, a manufacturing method of an array substrate may be derived from the present invention and it is different from the above-described manufacturing method of a vertical channel organic thin-film transistor in that a lower capacitor electrode plate, which is spaced from the source electrode 2, is formed on the base plate 1 at the same time of the formation of the source electrode 2 and an upper capacitor electrode plate is formed on a portion of the insulation layer 4 that is located atop the lower capacitor electrode plate at the same time of the formation of the drain electrode 5 such that the upper capacitor electrode plate is set in contact, through a via formed through the insulation layer 4, with an edge of an outer circle of the source electrode 2; and after the formation of the gate electrode 6, a passivation layer is set on and covers the gate electrode 6, the insulation layer 4, the drain electrode 5, and the upper capacitor electrode plate; a planarization layer is set on and covers the passivation layer; and a pixel electrode is finally formed on the planarization layer such that the pixel electrode is set in contact, through a through hole formed through the passivation layer and the planarization layer, with the drain electrode 5. The remaining is the same as those of the manufacturing method of a vertical channel organic thin-film transistor of the present invention and repeated description will be omitted.

It is noted that a vertical channel organic thin-film transistor that is manufactured with the vertical channel organic thin-film transistor manufacturing method is applicable to flexible flat panel display devices including flexible OLED display devices to fully exploit the characteristics of the organic thin-film transistor.

In summary, the present invention provides a vertical channel organic thin-film transistor, which comprises: an annular organic semiconductor layer, an annular drain electrode and an annular source electrode respectively set in contact with upper and lower sides of the annular organic semiconductor layer, and a gate electrode arranged inwardly of an inner circle of the annular organic semiconductor layer and insulated and isolated from the annular organic semiconductor layer, wherein an effective conductive channel length of the thin-film transistor can be varied by changing a thickness of the organic semiconductor layer made with a solution method so that the definition of a short channel pattern no longer relies upon high precision exposure and etching equipment and thus, the difficulty and the cost of the manufacturing process can be reduced. Further, the annular electrode structure makes it possible to save a planar space of the thin-film transistor, increasing scenarios of application of the thin-film transistor, and improving flexibility of circuit design. The present invention also provides a manufacturing method of a vertical channel organic thin-film transistor, which reduces manufacture difficulty and manufacturing cost of a short channel pattern and saves a planar space of the thin-film transistor.

Based on the description given above, those having ordinary skills in the art may easily contemplate various changes and modifications of the technical solution and the technical ideas of the present invention. All these changes and modifications are considered belonging to the protection scope of the present invention as defined in the appended claims.

What is claimed is:

1. A vertical channel organic thin-film transistor, comprising: a base plate, an annular source electrode arranged on the base plate, an annular organic semiconductor layer arranged on the source electrode and a portion of the base plate inwardly of an inner circle of the source electrode, an insulation layer set on and covering the base plate, the source electrode, and the organic semiconductor layer, an annular via extending through a portion of the insulation layer located atop the organic semiconductor layer, an annular drain electrode arranged in the annular via and in contact with the organic semiconductor layer, and a gate electrode arranged on a portion of the insulation layer inwardly of an inner circle of the organic semiconductor layer.

2. The vertical channel organic thin-film transistor as claimed in claim 1, wherein the source electrode, the organic semiconductor layer, the drain electrode, and the gate electrode have a common circle center.

3. The vertical channel organic thin-film transistor as claimed in claim 1, wherein the organic semiconductor layer is made with a solution method.

4. The vertical channel organic thin-film transistor as claimed in claim 1, wherein the vertical channel organic thin-film transistor is applicable to a flexible flat panel display device.

5. The vertical channel organic thin-film transistor as claimed in claim 1, wherein the organic semiconductor layer is formed of a material comprising a small-molecule organic semiconductor material or a polymer organic semiconductor material.

6. A manufacturing method of a vertical channel organic thin-film transistor, comprising the following steps:
Step 1: providing a base plate and forming an annular source electrode on the base plate;
Step 2: forming an annular organic semiconductor layer on the source electrode and a portion of the base plate inwardly of an inner circle of the source electrode;
Step 3: depositing an insulation layer on the base plate, the source electrode, and the organic semiconductor layer and subjecting the insulation layer to patterning to form an annular via that extends through a portion of the insulation layer located atop the organic semiconductor layer;
Step 4: forming an annular drain electrode in the annular via, such that the drain electrode is in contact with the organic semiconductor layer; and
Step 5: forming a gate electrode on a portion of the insulation layer inwardly of an inner circle of the organic semiconductor layer.

7. The manufacturing method of a vertical channel organic thin-film transistor as claimed in claim 6, wherein Step 2 applies a solution method to form the organic semiconductor layer and includes process that includes: coating or spin-coating an organic semiconductor material solution on the base plate and the source electrode, followed by baking and curing to form an organic semiconductor material film, and then subjecting the organic semiconductor material film to patterning to form the organic semiconductor layer.

8. The manufacturing method of a vertical channel organic thin-film transistor as claimed in claim 7, wherein in Step 2, subjecting the organic semiconductor material film to patterning is conducted by sequentially subjecting the organic semiconductor material film to exposure, development, and etching operations.

9. The manufacturing method of a vertical channel organic thin-film transistor as claimed in claim 6, wherein the organic semiconductor layer is formed of a material comprising a small-molecule organic semiconductor material or a polymer organic semiconductor material.

10. The manufacturing method of a vertical channel organic thin-film transistor as claimed in claim 6, wherein Step 1 includes: depositing a first metal film on the base plate 1 and then patterning the first metal film to form the annular source electrode;
Step 4 includes: depositing a second metal film on the insulation layer and then patterning the second metal film to form the annular drain electrode; and
Step 5 includes: depositing a third metal film on the insulation layer and then patterning the third metal film to form the gate electrode.

11. A vertical channel organic thin-film transistor, comprising: a base plate, an annular source electrode arranged on the base plate, an annular organic semiconductor layer arranged on the source electrode and a portion of the base plate inwardly of an inner circle of the source electrode, an insulation layer set on and covering the base plate, the source electrode, and the organic semiconductor layer, an annular via extending through a portion of the insulation layer located atop the organic semiconductor layer, an annular drain electrode arranged in the annular via and in contact with the organic semiconductor layer, and a gate electrode arranged on a portion of the insulation layer inwardly of an inner circle of the organic semiconductor layer;
wherein the source electrode, the organic semiconductor layer, the drain electrode, and the gate electrode have a common circle center; and
wherein the organic semiconductor layer is made with a solution method.

12. The vertical channel organic thin-film transistor as claimed in claim 11, wherein the vertical channel organic thin-film transistor is applicable to a flexible flat panel display device.

13. The vertical channel organic thin-film transistor as claimed in claim 11, wherein the organic semiconductor layer is formed of a material comprising a small-molecule organic semiconductor material or a polymer organic semiconductor material.
